(19) United States
(12) Patent Application Publication
(10) Pub. No.: US 2005/0231263 A1
(43) Pub. Date: Oct. 20, 2005

(54) Driver circuit

(75) Inventor: Shuhei Kawai, Ora-gun (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/108,064

(22) Filed: Apr. 18, 2005

(30) Foreign Application Priority Data
Apr. 19, 2004 (JP) 2004-122435

(51) Int. Cl. H03K 3/42; H01J 40/14

(52) U.S. Cl. 327/514; 250/214 R

(57) ABSTRACT

A driver circuit of a light emitting element is improved in efficiency. The driver circuit is to drive a white LED and includes a charge transfer device, a capacitor connected to the charge transfer device and a booster circuit that converts a power supply voltage inputted to the charge transfer device to a drive voltage of 1.5 times of the power supply voltage according to a clock applied to the capacitor. The drive voltage from the booster circuit is supplied to the white LED. The driver circuit also includes a pulse detection circuit that detects a brightness adjustment pulse BP and a switching circuit that controls a drive current to the white LED in order to adjust brightness of the white LED. The driver circuit includes a divider that reduces a frequency of the clock corresponding to a reduction in the drive current due to the brightness adjustment made by the switching circuit.

### CROSS-REFERENCE OF THE INVENTION

This invention is based on Japanese Patent Application No. 2004-122435, the content of which is incorporated herein by reference in its entirety.

### BACKGROUND OF THE INVENTION

1. Field of the Invention

This invention relates to a driver circuit, specifically to a driver circuit to drive a light emitting element.

2. Description of the Related Art

A white light emitting diode (hereafter referred to as a white LED) has been used as back light for a liquid crystal display panel. The white LED has a VF (forward voltage drop) ranging from 3.2V to 3.8V. A voltage as high as VF is to be applied across an anode and a cathode of the white LED to drive it to emit light. A power supply voltage ranging from 2.7V to 5.5V, for example, is required for the power supply voltage to the white LED driver circuit. Therefore, when a power supply voltage Vdd is too low, the power supply voltage has been boosted to 1.5 times of Vdd before being supplied to the white LED.

FIG. 14 shows such a driver circuit to drive the white LED 150. In the circuit shown in FIG. 14, an anode of the white LED 150 is provided with a boosted voltage of 1.5 Vdd from a 1.5 Vdd booster circuit 160, while a cathode of the white LED 150 is provided with a ground voltage Vss (0V) through a driver transistor 170. The 1.5 Vdd booster circuit 160 generates the voltage of 1.5 Vdd from the power supply voltage Vdd. The 1.5 Vdd booster circuit 160 is disclosed in Japanese Patent Application Publication No. 2001-231249.

The 1.5 Vdd booster circuit 160 needs to be formed of large size transistors in order to provide the white LED 150 with a large current that the white LED 150 requires to emit high brightness light. As a result, parasitic capacitance of the transistors increases. Then a current to charge or discharge the parasitic capacitance of the transistors becomes not negligible when an output current of the 1.5 Vdd booster circuit 160 is reduced for brightness adjustment of the white LED 150, causing a problem that efficiency of the 1.5 Vdd booster circuit 160 is exacerbated.

### SUMMARY OF THE INVENTION

This invention offers a circuit device that includes a charge transfer device, a capacitor connected to the charge transfer device, a voltage conversion circuit that converts an input voltage inputted to the charge transfer device into a predetermined drive voltage according to a clock inputted to the capacitor, a light emitting element to which the drive voltage from the voltage conversion circuit is applied, a brightness adjustment circuit that adjusts a brightness of the light emitting element by controlling a drive current of the light emitting element, and a clock frequency switching circuit that reduces a frequency of the clock in response to a reduction of the drive current controlled by the brightness adjustment circuit.

### BRIEF DESCRIPTION OF THE DRAWINGS

FIG. 1 is a circuit diagram of a driver circuit according to a first embodiment of this invention.

FIG. 2 is a circuit diagram of a divider in the driver circuit according to the first embodiment of this invention.

FIG. 3 shows operation of the driver circuit according to the first embodiment of this invention.

FIG. 4 is a timing chart showing the operation of the driver circuit according to the first embodiment of this invention.

FIGS. 5A and 5B are circuit diagrams of the driver circuit according to the first embodiment of this invention.

FIG. 6 is a timing chart showing operation of a booster circuit in the driver circuit according to the first embodiment of this invention.

FIG. 7 is a circuit diagram of a driver circuit according to a second embodiment of this invention.

FIGS. 8A and 8B are circuit diagrams of a −0.5 Vdd generation circuit in the driver circuit according to the second embodiment of this invention.

FIG. 9 is a timing chart showing operation of the −0.5 Vdd generation circuit in the driver circuit according to the second embodiment of this invention.

FIG. 10 is a circuit diagram of a driver circuit according to a third embodiment of this invention.

FIG. 11 is a circuit diagram of a voltage adjustment circuit in the driver circuit according to the third embodiment of this invention.

FIG. 12 shows operation of the driver circuit according to the third embodiment of this invention.

FIG. 13 is a circuit diagram of a driver circuit according to a fourth embodiment of this invention.

FIG. 14 is a circuit diagram of a driver circuit according to a prior art.

### DETAILED DESCRIPTION OF THE INVENTION

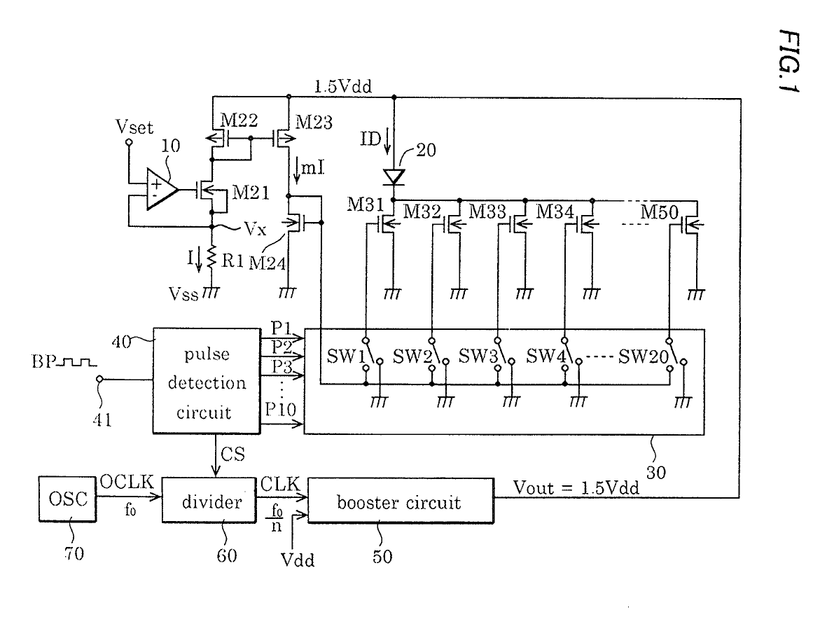

Next, a first embodiment of this invention will be explained hereinafter, referring to figures. FIG. 1 is a circuit diagram of a driver circuit according to the first embodiment.

A reference voltage Vset is applied to a positive input terminal (+) of an operational amplifier 10 serving as a voltage follower. An output of the operational amplifier 10 is applied to a gate of an N-channel type MOS transistor M21, and a negative input terminal (−) of the operational amplifier 10 is connected to a source of the N-channel type MOS transistor M21. A resistor R1 is connected between the source of M21 and a ground Vss. Therefore, a voltage Vx at the source of M21 is controlled by the operational amplifier 10 so that the voltage Vx becomes equal to the reference voltage Vset. As a result, a current I (=Vset/R1) is generated and flows through the resistor R1. The current I flows through a P-channel type MOS transistor M22 in a first current mirror circuit composed of a pair of P-channel type MOS transistors M22 and M23 (current ratio 1:m).

The first current mirror circuit multiplies the current I by m. The multiplied current mI is inputted to a second current mirror circuit that is in a form of fold-back of the first current mirror circuit. The second current mirror circuit includes an N-channel type MOS transistor M24 and 20 N-channel type MOS transistors M31 through M50. A switching circuit 30 switches each of the N-channel type MOS transistors M31 through M50 to decide whether each of the N-channel type MOS transistors M31 through M50 forms the second current mirror circuit or not together with the N-channel type MOS transistor M24.

For example, a gate of the N-channel type MOS transistor M31 is switched by switch SW1 to be connected to either a gate of the N-channel type MOS transistor M24 or the ground Vss. When the gate of the N-channel type MOS transistor M31 is connected to the gate of the N-channel type MOS transistor M24, these transistors are related to form a current mirror, thus a current mnI that is n times of the current mI flowing through the N-channel type MOS transistor M24 flows through the N-channel type MOS transistor M31.

When the gate of the N-channel type MOS transistor M31 is connected to the ground Vss, on the other hand, no current flows through the N-channel type MOS transistor M31. Each of the other N-channel type MOS transistors M32 through M50 is connected similarly with each of the other switches SW2 through SW20, respectively. Each of the switches SW1-SW20 may be formed of an inverter circuit.

As described above, the current mnI that is the current I multiplied by mn, flows through each of the MOS transistors selected from among the N-channel type MOS transistors M31 through M50 to provide a white LED 20 connected to the N-channel type MOS transistors M31 through M50 with a large current. Brightness adjustment of the white LED 20 is performed as described above.

Switching of the switches SW1-SW20 in the switching circuit 30 is performed according to pulse detection signals P1, P2, P3, P4, P5, P6, P7, P8, P9 and P10, as will be described hereinafter. A pulse detection circuit 40 counts brightness adjustment pulses BP applied to a brightness adjustment terminal 41.

A booster circuit 50 provides the white LED 20 with a boosted voltage. The booster circuit 50 includes charge transfer devices and capacitors connected with the charge transfer devices and converts a power supply voltage Vdd inputted to one of the charge transfer devices into 1.5 Vdd according to a clock applied to one of the capacitors. Detailed circuit structure and operation of the booster circuit will be described hereinafter.

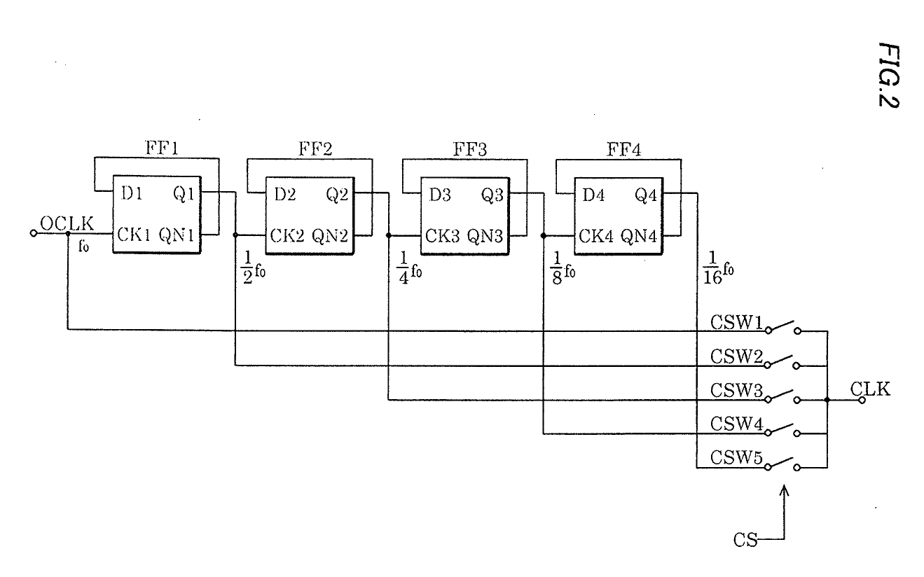

The booster circuit 50 is provided with a clock CLK from a divider 60. The divider 60 divides an oscillation clock OCLK from an oscillator OSC to generate a plurality of clocks having frequencies f₀, f₀/2, f₀/4, f₀/8 and f₀/16, as well as selectively outputting one of the clocks according to a result of detection by a pulse detection circuit 40. The divider 60 has a first flip flop FF1, a second flip flop FF2, a third flip flop FF3 and a fourth flip flop FF4, as shown in FIG. 2.

A first clock is obtained from the oscillation clock having the frequency f₀, a second clock having the frequency f₀/2 is obtained from an output terminal Q1 of the first flip flop FF1, a third clock having the frequency f₀/4 is obtained from an output terminal Q2 of the second flip flop FF2, a fourth clock having the frequency f₀/8 is obtained from an output terminal Q3 of the third flip flop FF3 and a fifth clock having the frequency f₀/16 is obtained from an output terminal Q4 of the fourth flip flop FF4.

And switches CSW1, CSW2, CSW3, CSW4 and CSW5 that are controlled by a clock frequency switching signal CS from the pulse detection circuit 40 select one of the first through fifth clocks mentioned above and output it as the clock CLK.

A variable frequency oscillator (a voltage controlled oscillator, for example) may be used instead of dividing the oscillation clock OCLK from the oscillator (OSC) 70 with the divider 60.

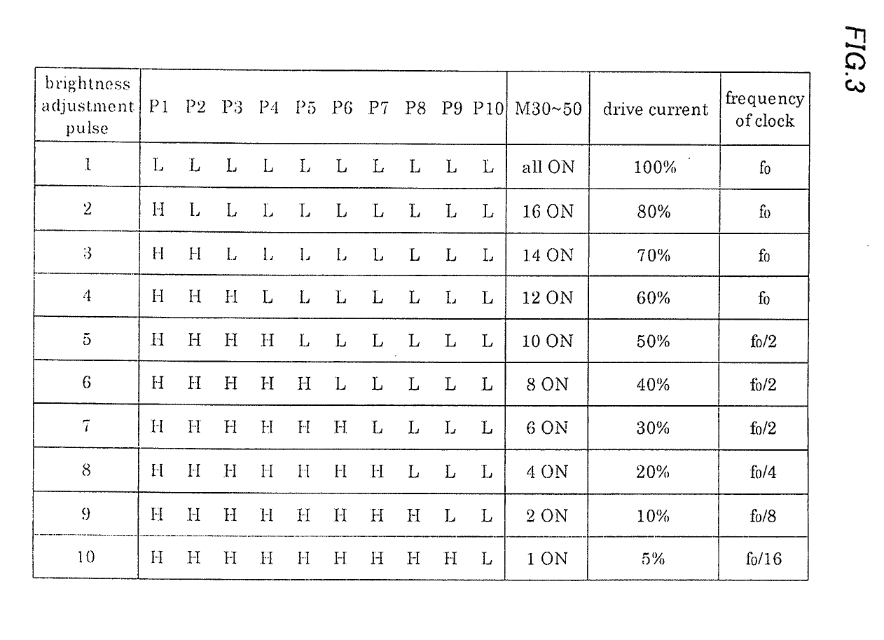

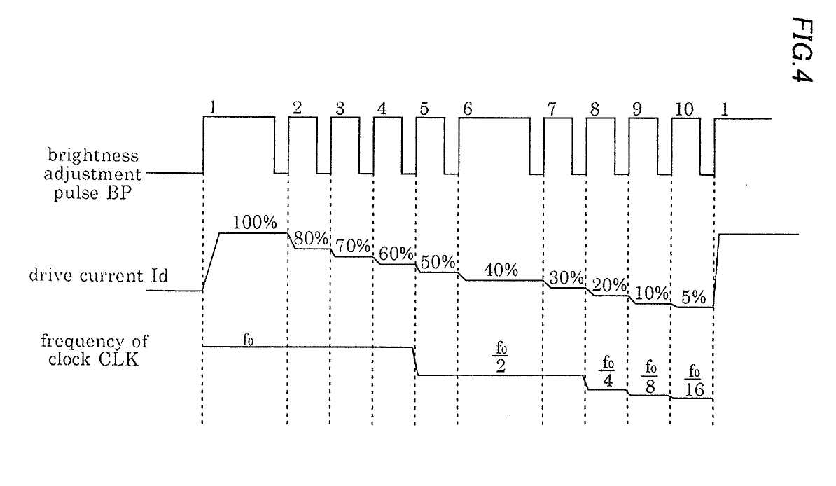

Operation of the driver circuit described above is explained referring to FIGS. 3 and 4. Assuming the switching circuit 30 is formed of inverters, all of the pulse detection signals P1 through P10 become an L level (low level) to turn on all of the 20 N-channel type MOS transistors M31 through M50 when a first brightness adjustment pulse BP is applied to the brightness adjustment terminal 41. That is, the switches SW1 through SW20 are switched so that all of the N-channel type MOS transistors M31 through M50 form current mirrors with the N-channel type MOS transistor M24. As a result, a drive current ID to the white LED 20 flows through all of the N-channel type MOS transistors M31 through M50, making the drive current ID a maximum value (100%). At that time, the switch CSW1 in the divider 60 is turned on by the clock frequency switching signal CS from the pulse detection circuit 40 and the divider 60 outputs the clock CLK having the frequency f₀ that is supplied to the booster circuit 50.

Next, when a second brightness adjustment pulse BP is applied, the pulse detection signal P1 is turned to an H level (high level) to switch the switches SW1 through SW20, so that 16 out of the 20 N-channel type MOS transistors M31 through M50 are turned on to form current mirrors with the N-channel type MOS transistor M24.

Since the drive current ID to the white LED 20 flows through only 16 out of the 20 N-channel type MOS transistors M31 through M50, the drive current ID drops to 80% of the maximum value.

Similarly, each time additional brightness adjustment pulse BP is applied to the brightness adjustment terminal 41, the pulse detection signals P1 through P10 turns to the H level one after another, reducing a number of transistors turned-on out of the 20 N-channel type MOS transistors M31 through M50, thus reducing the drive current ID and the brightness of the white LED 20. The clock CLK having the frequency f₀ is outputted from the divider 60 when the drive current ID to the white LED 20 is between 60% and 100% of the maximum value. This is because the booster circuit 50 is required to supply a considerably large output current for this range of the drive current.

When a fifth brightness adjustment pulse BP is applied, the drive current ID to the white LED 20 drops to 50% of the maximum value, because the drive current ID flows through only 10 out of the 20 N-channel type MOS transistors M31 through M50. At that time, the switch CSW1 is turned off and the switch CSW2 is turned on instead by the clock frequency switching signal CS from the pulse detection circuit 40 and the divider 60 outputs the clock CLK having the frequency f₀/2 that is supplied to the booster circuit 50. The divider 30 outputs the clock CLK having the frequency f₀/2, when the drive current ID to the white LED 20 is between 30% and 50% of the maximum value.

When an eighth brightness adjustment pulse BP is applied, the drive current ID to the white LED 20 drops to 20% of the maximum value, because the drive current ID flows through only 4 out of the 20 N-channel type MOS transistors M31 through M50. At that time, the switch CSW2 is turned off and the switch CSW3 is turned on instead by the clock frequency switching signal CS from the pulse detection circuit 40 and the divider 60 outputs the clock CLK having the frequency f₀/4 that is supplied to the booster circuit 50. Similarly when a ninth brightness adjustment pulse BP is applied, the drive current ID to the white LED 20 drops to 10% of the maximum value, because the drive current ID flows through only 2 out of the 20 N-channel type MOS transistors M31 through M50.

At that time, the switch CSW3 is turned off and the switch CSW4 is turned on instead by the clock frequency switching signal CS from the pulse detection circuit 40 and the divider 60 outputs the clock CLK having the frequency f₀/8 that is supplied to the booster circuit 50. Furthermore, when a tenth brightness adjustment pulse BP is applied, the drive current ID to the white LED 20 drops to 5% of the maximum value, because the drive current ID flows through only 2 out of the 20 N-channel type MOS transistors M31 through M50. At that time, the switch CSW4 is turned off and the switch CSW5 is turned on instead by the clock frequency switching signal CS from the pulse detection circuit 40 and the divider 60 outputs the clock CLK having the frequency f₀/16 that is supplied to the booster circuit 50.

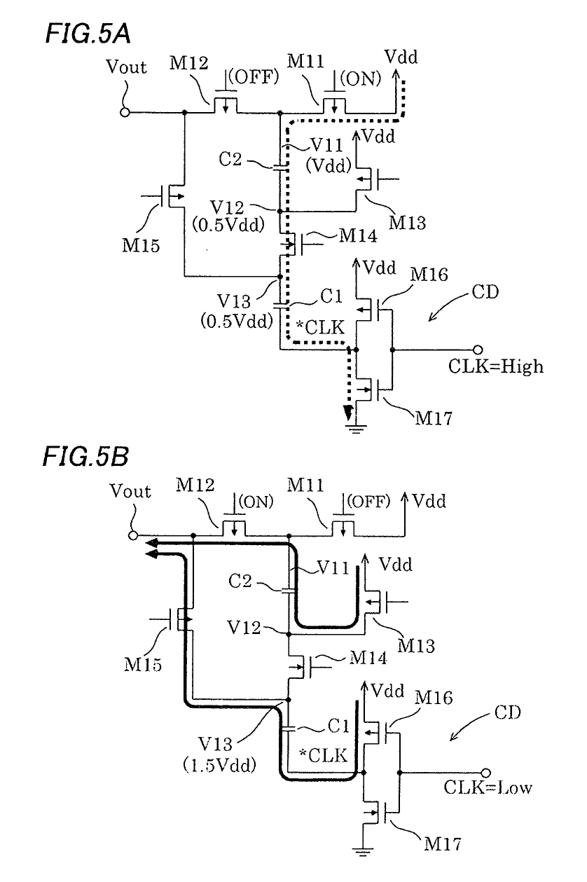

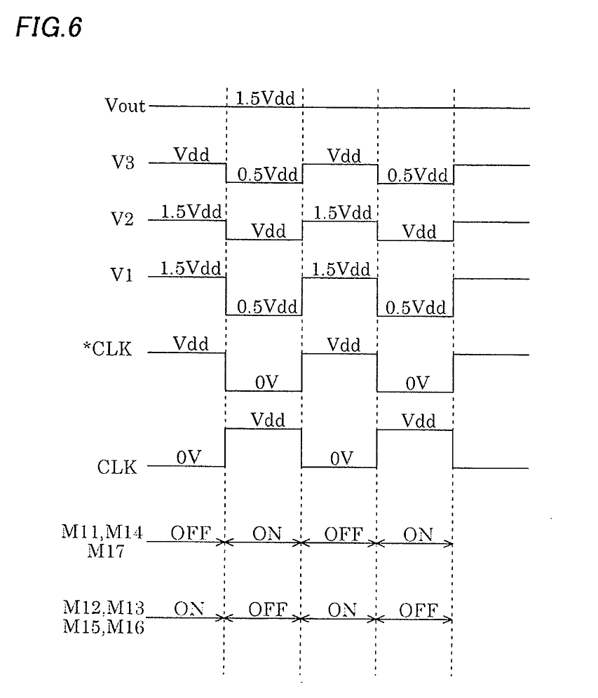

Next, a concrete circuit structure and the operation of the booster circuit 50 is explained, referring to FIGS. 5A, 5B and 6. FIG. 5A shows a case in which the clock CLK inputted from the divider 60 to a clock driver CD is at the H level, while FIG. 5B shows a case in which the clock CLK is at the L level.

The power supply voltage Vdd is applied to a source of a first switching MOS transistor M11. A drain of the first switching MOS transistor M11 is connected to a source of a second switching MOS transistor M12. The first switching MOS transistor M11 and the second switching MOS transistor M12 serve as charge transfer devices.

Both the first switching MOS transistor M11 and the second switching MOS transistor M12 are P-channel type. The reason is to obtain voltages to turn on and off the first switching MOS transistor M11 and the second switching MOS transistor M12 from voltages available within the circuit. The ground voltage Vss is applied to gates of the first switching MOS transistor M11 and the second switching MOS transistor M12 to turn them on, and an output voltage Vout (=1.5 Vdd) of the circuit is applied to the gates to turn them off.

An output of the clock driver CD is connected to a terminal of a first capacitor C1. The clock driver CD is a CMOS inverter composed of a P-channel type MOS transistor M16 and an N-channel type MOS transistor M17 connected in series between the power supply Vdd and the ground Vss. The clock CLK is inputted to the clock driver CD and inverted by the clock driver CD. A reverse clock *CLK, that is the output of the clock driver, is applied to the terminal of the first capacitor C1.

A terminal of a second capacitor C2 is connected to a connecting point between the first switching MOS transistor M11 and the second switching MOS transistor M12. A third switching MOS transistor M13 is connected between another terminal of the second capacitor C2 and the power supply Vdd.

A fourth switching MOS transistor M14 is connected between another terminal of the first capacitor C1 and the another terminal of the second capacitor C2. A fifth switching MOS transistor M15 is connected between the another terminal of the first capacitor C1 and an output terminal that is a drain of the second switching MOS transistor M12. The output voltage Vout (=1.5 Vdd) of the circuit is obtained from the drain of the second switching MOS transistor M12.

The third switching MOS transistor M13 and the fifth switching MOS transistor M15 are P-channel type, while the fourth switching MOS transistor M14 is N-channel type. The reason why the third switching MOS transistor M13 and the fifth switching MOS transistor M15 are P-channel type is to obtain voltages to turn on and off the third switching MOS transistor M13 and the fifth switching MOS transistor M15 from voltages available within the circuit, as described above.

It is assumed that a capacitance of the first capacitor C1 and a capacitance of the second capacitor C2 are equal to each other. Turning on and off of the first switching MOS transistor M11, the second switching MOS transistor M12, the third switching MOS transistor M13, the fourth switching MOS transistor M14 and the fifth switching MOS transistor M15 are controlled by controlling their gate voltages with a control circuit, that is not shown in the figure, according to a voltage level of the clock CLK, as will be described hereinafter.

Next, the operation of the circuit will be explained referring to FIGS. 5A and 5B and FIG. 6. FIG. 6 is a timing chart showing the operation of this charge pump circuit in a stationary state. The operation of the charge pump circuit when the clock CLK is at the H level is described first (Refer to FIG. 5A and FIG. 6.). The N-channel type MOS transistor M17 of the clock driver CD is turned on and a reverse clock *CLK is at the L level (0V). The first switching MOS transistor M11 and the fourth switching MOS transistor M14 are turned on while the second switching MOS transistor M12, the third switching MOS transistor M13 and the fifth switching MOS transistor M15 are turned off.

As a result, the first switching MOS transistor M11, the second capacitor C2, the fourth switching MOS transistor M14, the first capacitor C1 and the N-channel type MOS transistor M17 of the clock driver CD are connected in series between the power supply Vdd and the ground Vss as indicated by a dashed bold line in FIG. 5A, and the first capacitor C1 and the second capacitor C2 are charged. The terminal of the second capacitor C2 is charged to Vdd, a voltage V12 at the another terminal of the second capacitor C2 is charge to 0.5 Vdd and a voltage V13 at the another terminal of the first capacitor C1 is also charged to 0.5 Vdd.

The operation of the charge pump circuit when the clock CLK is at the L level will be described next (Refer to FIG. 5B and FIG. 6.). The P-channel type MOS transistor M16 of the clock driver CD is turned on and the reverse clock *CLK is at the H level. The first switching MOS transistor M11 and the fourth switching MOS transistor M14 are turned off while the second switching MOS transistor M12, the third switching MOS transistor M13 and the fifth switching MOS transistor M15 are turned on.

As a result, 1.5 Vdd is supplied to the output terminal through two paths indicated with solid bold lines in FIG. 5B. Charges in the second capacitor C2 is discharged to provide the output terminal with 1.5 Vdd through one of the paths that runs from the power supply Vdd to the output terminal through the third switching MOS transistor M13, the second capacitor C2 and the second switching MOS transistor M12. The voltage V12 at the another terminal of the second capacitor C2 has been charged to 0.5 Vdd when the clock CLK is at the H level. The voltage V11 at the terminal of the second capacitor C2 is pulled up from Vdd to 1.5 Vdd by capacitive coupling through the second capacitor C2 when the voltage V12 varies from 0.5 Vdd to Vdd by turning-on of the third switching MOS transistor M13.

Charges in the first capacitor C1 is discharged to provide the output terminal with 1.5 Vdd through another of the paths that runs from the power supply Vdd to the output terminal through the P-channel type MOS transistor M16 of the clock driver CD, the first capacitor C1 and the fifth switching MOS transistor M15.

The voltage V13 at the another terminal of the first capacitor C1 has been charged to 0.5 Vdd when the clock CLK is at the H level. The voltage V13 at the another terminal of the first capacitor C1 is pulled up from 0.5 Vdd to 1.5 Vdd by capacitive coupling through the first capacitor C1, as the voltage at the terminal of the first capacitor C1 varies from 0V to Vdd by turning-on of the P-channel type MOS transistor M16 when the clock CLK turns to the L level.

The output voltage Vout of 1.5 Vdd that is the power supply voltage Vdd multiplied by 1.5 is obtained by alternately repeating the operation when the clock CLK is at the H level and the operation when the clock CLK is at the L level.

Assuming a parasitic capacitance of the booster circuit 50 is Cp, the frequency of the clock CLK is f and a voltage amplitude of the clock CLK is V, a self consumption current Ip is represented as Ip=Cp×f×V. The self consumption current Ip can be reduced by reducing the frequency f of the clock CLK. The parasitic capacitance Cp of the booster circuit 50 is made of parasitic capacitance (mainly gate capacitance) of the charge transfer devices (the first switching MOS transistor M11 and the second switching MOS transistor M12) forming the booster circuit 50 and the clock driver CD.

Now assuming the self consumption current Ip is 5 mA and the output current Iout is 100 mA, the efficiency (=Iout×100/(Iout+Ip)) of the booster circuit 50 is 100×100/(100+5)=95%. However, when the output current Iout is reduced to 5 mA while the frequency f of the clock CLK remains intact, the efficiency of the booster circuit 50 is reduced to 5×100/(5+5)=50%. The self consumption current Ip can be reduced to improve the efficiency of the booster circuit 50 by reducing the frequency f of the clock CLK to 1/16, for example, when the output current Iout is reduced to 5 mA. The efficiency is 5×100/(5+0.3)=94% in this case.

According to the driver circuit of this embodiment, as described above, because the frequency of the clock CLK supplied to the booster circuit 50 is reduced corresponding to the reduction in the drive current ID to the white LED 20, charging/discharging current to/from the parasitic capacitance (mainly gate capacitance) of the charge transfer devices (the first switching MOS transistor M11 and the second switching MOS transistor M12) forming the booster circuit 50 and the clock driver CD is also reduced. Thus the efficiency of the booster circuit 50 is improved, leading to improvement in the efficiency of the driver circuit.

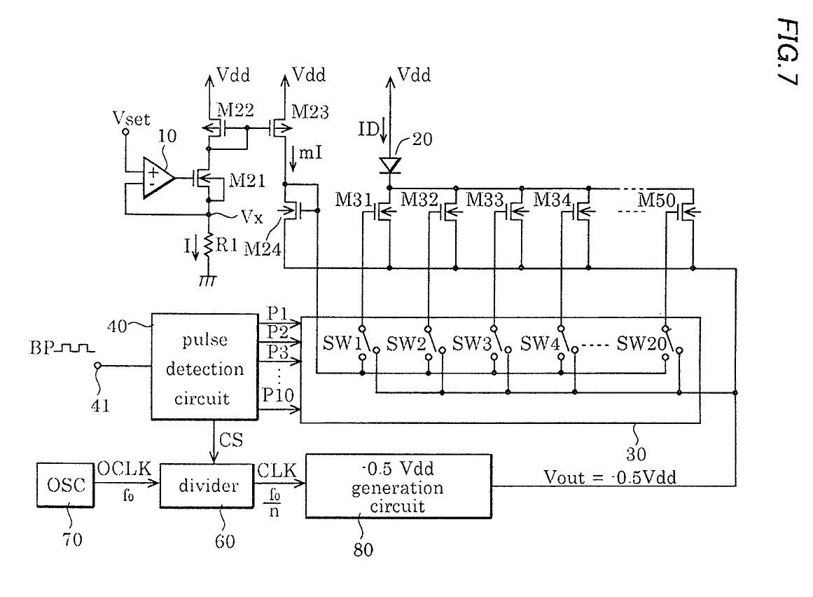

Next, a second embodiment of this invention is explained. FIG. 7 is a circuit diagram of a driver circuit according to the second embodiment. The booster circuit 50 in the first embodiment is replaced with a −0.5 Vdd generation circuit 80 in the second embodiment. Vdd is applied to an anode of a white LED 20 while −0.5 Vdd is applied to a cathode of the white LED 20 in this embodiment. A voltage across the anode and the cathode of the white LED 20 is the same 1.5 Vdd as in the first embodiment. Also, −0.5 Vdd is applied to sources of N-channel type MOS transistors M24 and M31 through M50.

In addition, −0.5 Vdd is applied to gates of the N-channel type MOS transistors M31 through M50 when switches SW1 through SW20 in a switching circuit 30 turn off the N-channel type MOS transistors M31 through M50. The other structural features are the same as in the first embodiment.

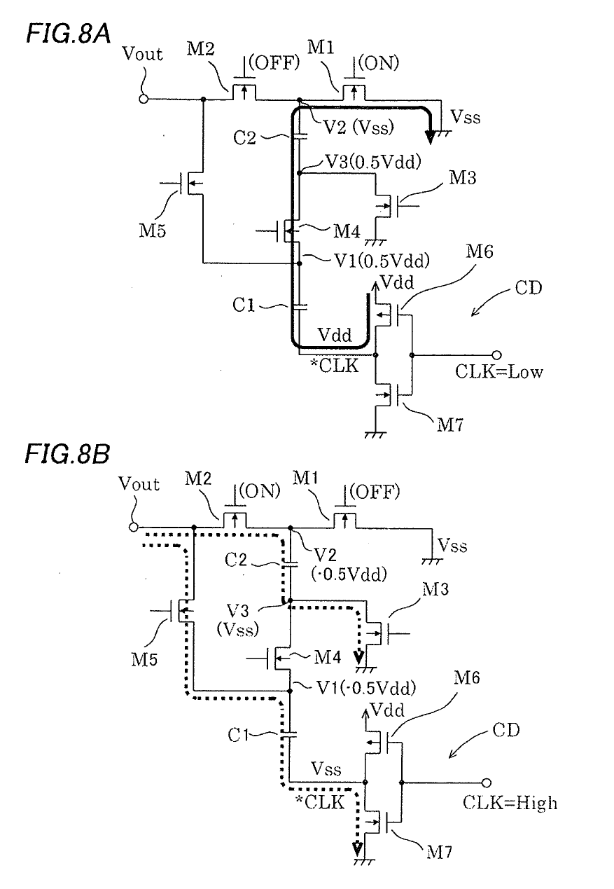

Next, a concrete structure and operation of the −0.5 Vdd generation circuit 80 will be explained referring to figures. FIGS. 8A and 8B are circuit diagrams of the −0.5 Vdd generation circuit 80. FIG. 8A shows a status of the circuit when the clock CLK inputted to a clock driver CD is at the L level, while FIG. 8B shows a status of the circuit when the clock CLK is at the H level.

The ground voltage Vss (0V) is applied to a source of a first switching MOS transistor M1. A drain of the first switching MOS transistor M1 is connected to a source of a second switching MOS transistor M2. The first switching MOS transistor M1 and the second switching MOS transistor M2 serve as charge transfer devices.

Both the first switching MOS transistor M1 and the second switching MOS transistor M2 are N-channel type. The reason is to obtain voltages to turn on and off the first switching MOS transistor M1 and the second switching MOS transistor M2 from voltages available within the circuit. The power supply voltage Vdd is applied to gates of the first switching MOS transistor M1 and the second switching MOS transistor M2 to turn them on, and an output voltage Vout (=−0.5 Vdd) of the circuit is applied to the gates to turn them off.

An output of the clock driver CD is connected to a terminal of a first capacitor C1. The clock driver CD is a CMOS inverter composed of a P-channel type MOS transistor M6 and an N-channel type MOS transistor M7 connected in series between the power supply Vdd and the ground Vss. The clock CLK is inputted to the clock driver CD and inverted by the clock driver CD. A reverse clock *CLK, that is the output of the clock driver, is applied to the terminal of the first capacitor C1.

Alternatively, a clock CLK' made by delaying the clock CLK may be applied to a gate of the N-channel type MOS transistor M7 while the clock CLK is applied to a gate of the P-channel type MOS transistor M6 in order to reduce a through-current flowing through the clock driver CD.

A terminal of a second capacitor C2 is connected to a connecting point between the first switching MOS transistor M1 and the second switching MOS transistor M2. A third switching MOS transistor M3 is connected between another terminal of the second capacitor C2 and the ground Vss (0V).

A fourth switching MOS transistor M4 is connected between another terminal of the first capacitor C1 and the another terminal of the second capacitor C2. A fifth switching MOS transistor M5 is connected between the another terminal of the first capacitor C1 and an output terminal that is a drain of the second switching MOS transistor M2. The output voltage Vout (=−0.5 Vdd) of the circuit is obtained from the drain of the second switching MOS transistor M2.

The third switching MOS transistor M3 and the fifth switching MOS transistor M5 are N-channel type. The reason is to obtain voltages to turn on and off the third switching MOS transistor M3 and the fifth switching MOS transistor M5 from voltages available within the circuit, as in the case of the first switching MOS transistor M1 and the second switching MOS transistor M2. That is, the power supply voltage Vdd is applied to gates of the third switching MOS transistor M3 and the fifth switching MOS transistor M5 to turn them on, and the output voltage Vout (=−0.5 Vdd) of the circuit is applied to the gates to turn them off.

Although the fourth switching MOS transistor M4 may be either P-channel type or N-channel type, N-channel type is preferable to reduce a patterning area. The power supply voltage Vdd is applied to a gate of the fourth switching MOS transistor M4 to turn it on and the output voltage Vout (=−0.5 Vdd) of the circuit is applied to the gate to turn it off, when the fourth switching MOS transistor M4 is N-channel type. The ground voltage Vss or the output voltage Vout is applied to the gate of the fourth switching MOS transistor M4 to turn it on and the power supply voltage Vdd is applied to the gate to turn it off, when the fourth switching MOS transistor M4 is P-channel type.

It is assumed that a capacitance of the first capacitor C1 and a capacitance of the second capacitor C2 are equal to each other. Turning on and off of the first switching MOS transistor M1, the second switching MOS transistor M2, the third switching MOS transistor M3, the fourth switching MOS transistor M4 and the fifth switching MOS transistor M5 are controlled by controlling their gate voltages with a control circuit, that is not shown in the figure, according to a voltage level of the clock CLK, as will be described hereinafter.

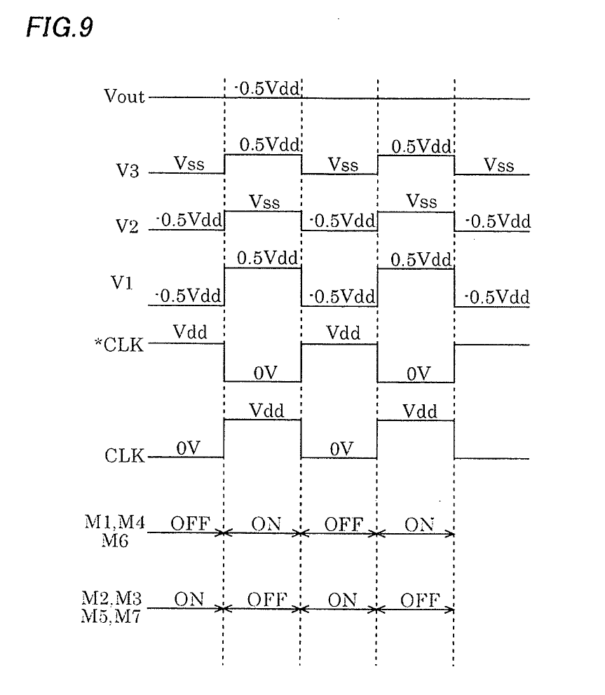

Next, operation of the −0.5 Vdd generation circuit 80 will be explained referring to FIGS. 8A and 8B and FIG. 9. FIG. 9 is a timing chart showing the operation of the −0.5 Vdd generation circuit 80 in a stationary state.

The operation of the charge pump circuit when the clock CLK is at the L level is described first (Refer to FIG. 8A and FIG. 9.). Since the P-channel type MOS transistor M6 of the clock driver CD is turned on while the N-channel type MOS transistor M7 is turned off, the reverse clock *CLK is at the H level (Vdd). The first switching MOS transistor M1 and the fourth switching MOS transistor M4 are turned on while the second switching MOS transistor M2, the third switching MOS transistor M3 and the fifth switching MOS transistor M5 are turned off.

As a result, the P-channel type MOS transistor M6 of the clock driver CD, the first capacitor C1, the fourth switching MOS transistor M4, the second capacitor C2 and the first switching MOS transistor M1 are connected in series between the power supply Vdd and the ground Vss as indicated with a solid bold line in FIG. 8A, and the first capacitor C1 and the second capacitor C2 are charged.

The terminal of the first capacitor C1 is charged to Vdd, a voltage V1 at the another terminal of the first capacitor C1 is charge to 0.5 Vdd and a voltage V3 at the another terminal of the second capacitor C2 is also charged to 0.5 Vdd.

The operation of the circuit when the clock CLK is at the H level will be described next (Refer to FIG. 8B and FIG. 9.). Since the N-channel type MOS transistor M7 of the clock driver CD is turned on while the P-channel type MOS transistor M6 is turned off, the reverse clock *CLK becomes to the L level (Vss). The first switching MOS transistor M1 and the fourth switching MOS transistor M4 are turned off while the second switching MOS transistor M2, the third switching MOS transistor M3 and the fifth switching MOS transistor M5 are turned on.

As a result, −0.5 Vdd is supplied to the output terminal through two paths indicated with dashed bold lines in FIG. 8B. Charges in the second capacitor C2 is discharged to provide the output terminal with −0.5 Vdd through one of the paths that runs from the ground Vss to the output terminal through the third switching MOS transistor M3, the second capacitor C2 and the second switching MOS transistor M2. The voltage V3 at the another terminal of the second capacitor C2 has been charged to 0.5 Vdd when the clock CLK is at the L level. A voltage V2 at the terminal of the second capacitor C2 is pulled down from Vss (0V) to −0.5 Vdd by capacitive coupling through the second capacitor C2 when the voltage V3 varies from 0.5 Vdd to Vss by turning-on of the third switching MOS transistor M3.

Charges in the first capacitor C1 is discharged to provide the output terminal with −0.5 Vdd through another of the paths that runs from the ground Vss to the output terminal through the N-channel type MOS transistor M7 of the clock driver CD, the first capacitor C1 and the fifth switching MOS transistor M5. The voltage V1 at the another terminal of the first capacitor C1 has been charged to 0.5 Vdd when the clock CLK is at the L level. The voltage V1 at the another terminal of the first capacitor C1 is pulled down from 0.5 Vdd to −0.5 Vdd by capacitive coupling through the first capacitor C1 when the voltage at the terminal of the first capacitor C1 varies from Vdd to Vss by turning-on of the N-channel type MOS transistor M7 when the clock CLK turns to the H level.

The output voltage Vout of −0.5 Vdd that is the power supply voltage Vdd multiplied by −0.5 is obtained by alternately repeating the operation when the clock CLK is at the L level and the operation when the clock CLK is at the H level. Because the embodiment adopts the −0.5 Vdd generation circuit 80 in which N-channel type MOS transistors are heavily used, the driver circuit requires less patterning area to obtain the same amount of current mnI to drive the LED 20 as in the prior art, leading to an improved efficiency.

In the driver circuit of this embodiment, as described above, because the frequency of the clock CLK supplied to the −0.5 Vdd generation circuit 80 is reduced corresponding to the reduction in the drive current ID to the white LED 20, charging/discharging current to/from the parasitic capacitance (mainly gate capacitance) of the charge transfer devices (the first switching MOS transistor M1 and the second switching MOS transistor M2) forming the −0.5 Vdd generation circuit 80 and the clock driver CD is also reduced. Thus the efficiency of the −0.5 Vdd generation circuit 80 is improved, leading to improvement in the efficiency of the driver circuit.

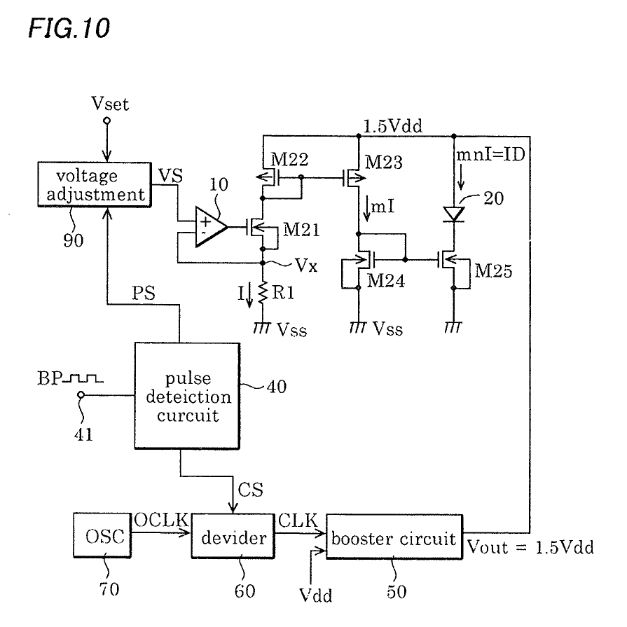

Next, a third embodiment of this invention is explained. FIG. 10 is a circuit diagram of a driver circuit according to this embodiment. While the drive current ID to the white LED 20 is controlled digitally for the brightness adjustment of the white LED 20 using the switching circuit 30 in the first and second embodiments, the drive current ID to the white LED 20 is controlled by analog control using a voltage adjustment circuit 90 in this embodiment. The other structural features are similar to the first embodiment. The voltage adjustment circuit 90 converts a reference voltage Vset into another reference voltage VS according to a voltage adjustment signal PS from a pulse detection circuit 40.

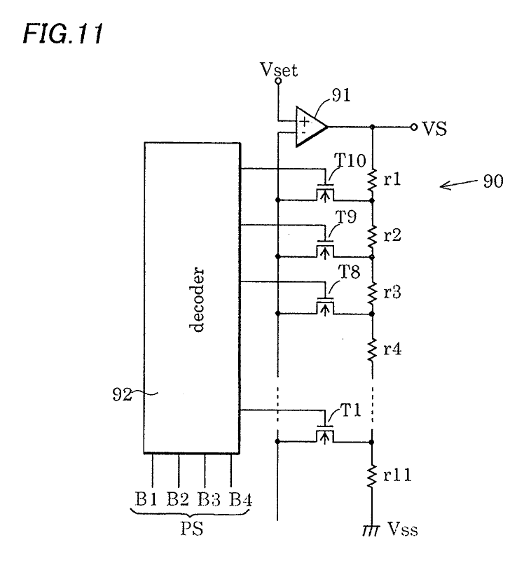

FIG. 11 is a circuit diagram showing the voltage adjustment circuit 90. The reference voltage Vset is applied to a positive input terminal (+) of an operational amplifier 91. Eleven resistors r1, r2, r3, r4, r5, r6, r7, r8, r9, r10 and r11 are connected between an output of the operational amplifier 91 and the ground Vss. Each of ten N-channel type MOS transistors T1, T2, T3, T4, T5, T6, T7, T8, T9 and T10 is connected between each connecting point between the resistors and a negative input terminal (−) of the operational amplifier 91.

Four bits of voltage adjustment data (B1, B2, B3 and B4) corresponding to the voltage adjustment signal PS from the pulse detection circuit 40 are inputted to a decoder 92. Each output signal of the decoder 92 is applied to each gate of the ten N-channel MOS type transistors T1 through T10. One of the transistors is turned on based on the voltage adjustment data (B1, B2, B3 and B4).

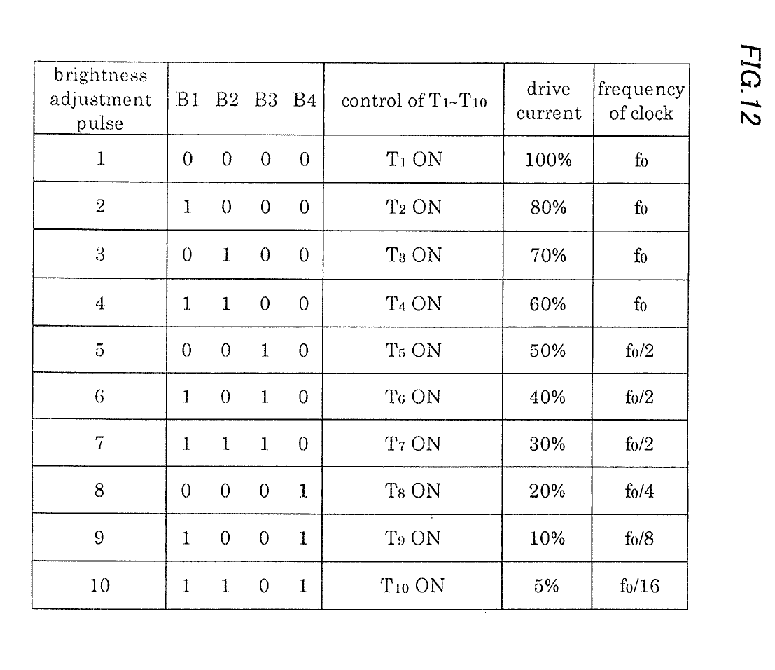

FIG. 12 explains the operation of this driver circuit. When a first brightness adjustment pulse BP is applied to a brightness adjustment terminal 41 of the pulse detection circuit 40, the pulse detection circuit 40 provides the voltage adjustment circuit 90 with voltage adjustment data (0, 0, 0, 0). As a result, only the N-channel type MOS transistor T1 is turned on, and VS=VS1 is generated accordingly. VS1 is expressed in the following equation.
VS1=Vset×(R+r11)/r11, where R=r1+r2+r3+r4+r5+r6+r7+r8+r9+r10.

A voltage Vx at a source of an N-channel type MOS transistor M22 is controlled by an operational amplifier 10 so that the voltage Vx becomes equal to the reference voltage VS. As a result, a current I1 (=VS1/R1) is generated and flows through a resistor R1. The current I1 flows through a P-channel type MOS transistor M22 in a first current mirror circuit composed of a pair of P-channel type MOS transistors M22 and M23 (current ratio 1:m). The first current mirror circuit multiplies the current I1 by m. The multiplied current mI1 is inputted to a second current mirror circuit that is in a form of fold-back of the first current mirror circuit. The second current mirror circuit is composed of a pair of N-channel type MOS transistors M24 and M25 (current ratio 1:n). The current mI1 is further multiplied by n by the second current mirror circuit and becomes a drive current ID (ID=mnI1) to the white LED 20.

When a second brightness adjustment pulse BP is applied to the brightness adjustment terminal 41 of the pulse detection circuit 40, the pulse detection circuit 40 provides the voltage adjustment circuit 90 with voltage adjustment data (1, 0, 0, 0). As a result, only the N-channel type MOS transistor T2 is turned on, and VS=VS2 is generated accordingly. Here, VS2 is lower than VS1. As a result, a current I2 flowing through the resistor R1 becomes smaller than the current I1. Therefore the drive current ID to the white LED 20 also becomes smaller.

The drive current ID to the white LED 20 is adjusted by analog control using the voltage adjustment circuit 90 as described above. Resistances of the resistors r1 through r11 are set so that the drive current ID to the white LED 20 varies from 100% to 5% depending on the voltage adjustment data (B1, B2, B3 and B4), as shown in FIG. 12.

It is the same as in the first embodiment that the frequency f of the clock CLK supplied to the booster circuit 50 is controlled by the clock frequency switching signal CS from the pulse detection circuit 40.

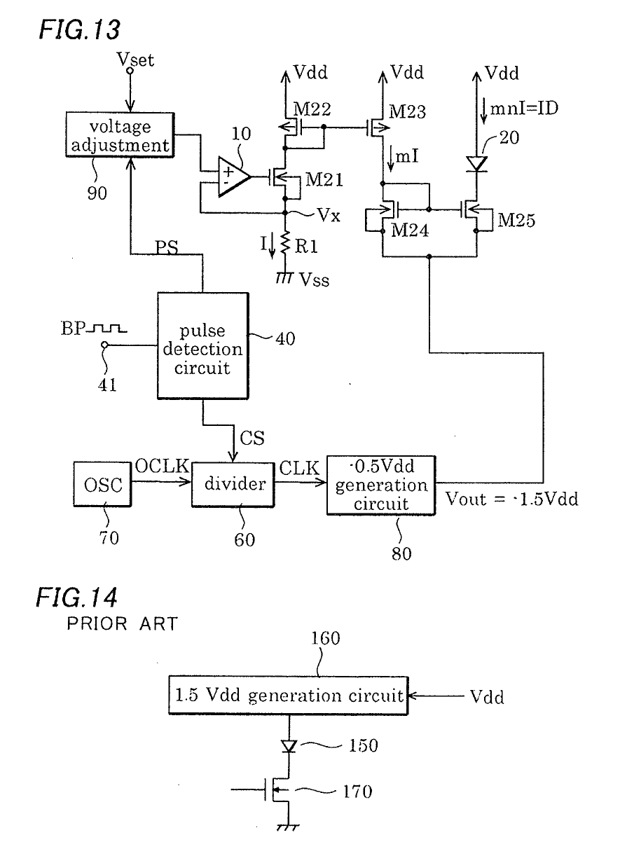

Next, a fourth embodiment of this invention is explained. FIG. 13 is a circuit diagram of a driver circuit according to this embodiment. The booster circuit 50 in the third embodiment is replaced with a −0.5 Vdd generation circuit 80 in this embodiment. Vdd is applied to an anode of a white LED 20 while −0.5 Vdd is applied to a cathode of the white LED 20 in this embodiment. A voltage across an anode and a cathode of the white LED 20 is the same 1.5 Vdd as in the third embodiment. The other structural features are the same as in the third embodiment.

It should be noted that this invention can be applied not only to the driver circuit of the white LED 20 but also to a driver circuit of a red LED, a green LED, a blue LED or other light emitting elements having an anode and a cathode.

According to this invention, when the drive current to the light emitting element is reduced, the frequency of the clock supplied to the voltage conversion circuit (booster circuit, for example) is also reduced accordingly. Therefore, the charging/discharging current to/from the parasitic capacitance of the charge transfer devices forming the voltage conversion circuit and the clock driver and the like is reduced to improve the efficiency of the driver circuit.

1. A circuit device comprising:
a charge transfer device;
a capacitor connected to the charge transfer device;
a voltage conversion circuit that converts an input voltage inputted to the charge transfer device into a predetermined drive voltage according to a clock inputted to the capacitor;
a light emitting element to which the drive voltage from the voltage conversion circuit is applied;
a brightness adjustment circuit that adjusts a brightness of the light emitting element by controlling a drive current of the light emitting element; and
a clock frequency modulation circuit that reduces a frequency of the clock in response to a reduction of the drive current controlled by the brightness adjustment circuit.

2. The driver circuit of claim 1, further comprising a plurality of current supply transistors each of which provides the light emitting element with a current, a pulse detection circuit that detects a brightness adjustment pulse inputted thereto, and a switching circuit that activates one of the current supply transistors in response to a result of a pulse detection made by the pulse detection circuit.

3. The driver circuit of claim 2, wherein the clock frequency modulation circuit comprises a divider that generates a plurality of clocks each having different frequencies by dividing a frequency of an oscillation clock generated by an oscillator, and a selector that selects one of the clocks according to the result of pulse detection made by the pulse detection circuit and provides the voltage conversion circuit with the selected clock.

4. The driver circuit of claim 1, wherein the brightness adjustment circuit comprises a current supply transistor that provides the light emitting element with at least a portion of the drive current, a voltage-current conversion circuit that receives a voltage and converts the voltage into a current that flows through the current supply transistor, a pulse detection circuit that detects a brightness adjustment pulse inputted thereto, and a voltage adjustment circuit that produces the voltage received by the voltage-current conversion circuit so that an magnitude of the voltage varies according to a result of pulse detection made by the pulse detection circuit.

5. The driver circuit of claim 4, wherein the clock frequency modulation circuit comprises a divider that generates a plurality of clocks each having different frequencies by dividing a frequency of an oscillation clock generated by an oscillator, and a selector that selects one of the clocks according to the result of pulse detection made by the pulse detection circuit and provides the voltage conversion circuit with the selected clock.

6. The driver circuit of claim 1, wherein the voltage conversion circuit multiplies the input voltage by 1.5.

7. The driver circuit of claim 1, wherein the voltage conversion circuit multiplies the input voltage by −0.5.

8. The driver circuit of claim 1, wherein the light emitting element comprises a white light emitting diode.
